(19) United States
(12) Patent Application Publication
(10) Pub. No.: US 2002/0111005 A1
(43) Pub. Date: Aug. 15, 2002

(54) Method of forming a contact pad

(76) Inventors: Hsin-Hui Hsu, chu-Tung Town (TW); Wan-Jeng Lin, Pan-Chiao City (TW); De-Yuan Wu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/779,464

(22) Filed: Feb. 9, 2001

(51) Int. Cl. H01L 21/44

(52) U.S. Cl. 438/612; 438/659; 438/669

(57) ABSTRACT

A method of forming a contact pad on a semiconductor wafer is achieved. A first photoresist layer is formed on the surface of a substrate, expect in a region where the contact pad will be formed. A nitrogen ion implantation is performed on the substrate uncovered by the first photoresist layer, followed by the complete removal of the first photoresist layer. Next, a silicon oxide layer is grown on the substrate, except in the region for the formation of the contact pad. Two adjacent MOS transistors are formed on the silicon oxide layer. A conductive layer is formed on the surface of the substrate to cover the two MOS transistors as well as to fill in the gap between the two MOS transistors. A patterned second photoresist layer is subsequently formed on the surface of the conductive layer to define the patterns of the contact pad. Finally, the conductive layer is etched down to the tops of the two adjacent MOS transistors and the surface of the silicon oxide layer to complete the fabrication of the contact pad.

### BACKGROUND OF THE INVENTION

1. Field of the Invention

The present invention relates to a method of forming a contact pad, and more particularly, to a method of forming a contact pad of a metal-oxide semiconductor (MOS) transistor.

2. Description of the Prior Art

A memory cell of a dynamic random access memory (DRAM) is composed of a MOS transistor, a capacitor and a contact plug. The MOS transistor functions in transporting charges, the capacitor functions in storing data and the contact plug functions as a node contact to connect the MOS transistor with the capacitor. As the design of elements become smaller, the process margin is reduced, to increase the difficulty of etching a node contact hole to precisely define the position of the contact plug. Hence, a contact pad is needed to ensure process quality.

The prior method of forming a contact pad 30 is performed on a semiconductor wafer 10. As shown in FIG. 1, the semiconductor wafer 10 comprises a silicon substrate 12, a gate oxide layer 14 positioned on the surface of the silicon substrate 12, at least one gate 22 of the MOS transistor positioned on a predetermined region of the gate oxide layer 14, and spacers 24 positioned on either side of each gate 22. The gate 22 comprises a doped polysilicon layer 16 positioned on the predetermined region of the gate oxide layer 14, a polycide layer 18 of titanium silicide (TiSiₓ) positioned on the doped polysilicon layer 16 to reduce junction resistance of the doped polysilicon layer 16, and a passivation layer 20 of silicon nitride positioned on the polycide layer 18 to prevent contact of the polycide 18 with the conductors within the contact pad 30 and thereby short circuiting.

As shown in FIG. 2, the prior contact pad 30 is formed by performing a chemical vapor deposition (CVD) process to deposit a dielectric layer 26 on the surface of the semiconductor wafer 10. The dielectric layer 26 is formed of silicon dioxide (SiO₂) and completely covers the gap between the two adjacent gates 22. As shown in FIG. 3, a planarization process such as chemical-mechanical polishing (CMP) or an etching back process is performed to produce a flat surface of the dielectric layer 26. Subsequently, a photoresist layer (not shown) is formed on the surface of the semiconductor wafer 10 followed by a photolithographic process to define the pattern of a node contact hole on the photoresist layer. A dry etching process is performed on the defined pattern to remove the portions of both the dielectric layer 26 and the gate oxide layer 14 located between the two gates 22 down to the surface of the silicon substrate 12, to form a node contact hole 28. After the removal of the photoresist layer, a CVD process is performed to deposit a doped polysilicon layer (not shown) on the surface of the semiconductor wafer 10 to completely cover the node contact hole 28. Finally, another CVD process is performed to remove a portion of the doped polysilicon layer, so that the doped polysilicon layer remaining in the node contact hole 28 is approximately aligned with the surface of the dielectric layer 26 to complete the formation of the contact pad 30.

The prior method uses the self-aligned contact (SAC) technology to form the node contact hole 28, whereby the spacers 24 and the passivation layer 20, composed of silicon nitride, are used as shields to etch the dielectric layer 26 via a fluorocarbon plasma etching process. However, the SAC technology requires high selectivity between the shielding mask and the material being etched. For example, when using fluoroform (CHF₃) as the etching gas, the selectivity for CHF₃ etching between the silicon nitride (Si₃N₄) mask and the etched silicon dioxide (SiO₂) is only 2˜4, so that destruction of the spacer 24 easily occurs, as shown in FIG. 3. As a result, the uniformity of deposition of the doped polysilicon layer on the whole surface of the semiconductor wafer 10 is inevitably affected to reduce production yield of the contact pad 30.

In addition, the prior method deposits the passivation layer 20, with a thickness of 1500 angstroms, to prevent structural destruction of the gate 22 during the etching process. However, the thickness of the passivation 20 results in high stress affected on the silicon nitride, which can lead to stripping of the whole passivation layer 20 and thereby result in current leakage of the gate 22.

In addition, a height difference exists between the silicon substrate 12 within the node contact hole 28 and the dielectric layer 26 surrounding the node contact hole 28. As well, the gap between the two adjacent gates 22 becomes narrower as element integration gradually increases. As a result, the increasing aspect ratio produces greater difficulty in filling conductors into the contact pad 30, which can lead to the formation of voids within the contact pad 30 to affect its electrical performance.

### SUMMARY OF THE INVENTION

It is therefore an objective of the present invention to provide a method of forming a contact pad to solve the above-mentioned problems.

In a preferred embodiment, the present invention provides a method of forming a contact pad on a semiconductor wafer. Firstly, a first photoresist layer is formed on the surface of a substrate, expect in a region where the contact pad will be formed. A nitrogen ion implantation is performed on the substrate uncovered by the first photoresist layer followed by the complete removal of the first photoresist layer. Next, a silicon oxide layer is grown on the substrate, except in the region where the contact pad will be formed. Two adjacent MOS transistors are formed on the silicon oxide layer. Next, a conductive layer is formed on the surface of the substrate to cover the two MOS transistors as well as to fill in the gap between the two MOS transistors. A patterned second photoresist layer is subsequently formed on the surface of the conductive layer to define the patterns of the contact pad. Finally, the conductive layer is etched down to the tops of the two adjacent MOS transistors and the surface of the silicon oxide layer to complete the fabrication of the contact pad.

It is an advantage of the present invention that the conductive layer is directly deposited between the two transistors, followed by the fabrication of the contact pad. By doing so, the etching process of the node contact hole is no longer required which prevents problems resulting from the etching process and thus, improve the electrical performance of the contact pad.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 3 are schematic diagrams of a prior art method of forming a contact pad.

FIG. 4 to FIG. 8 are schematic diagrams of forming a contact pad according to the present invention.

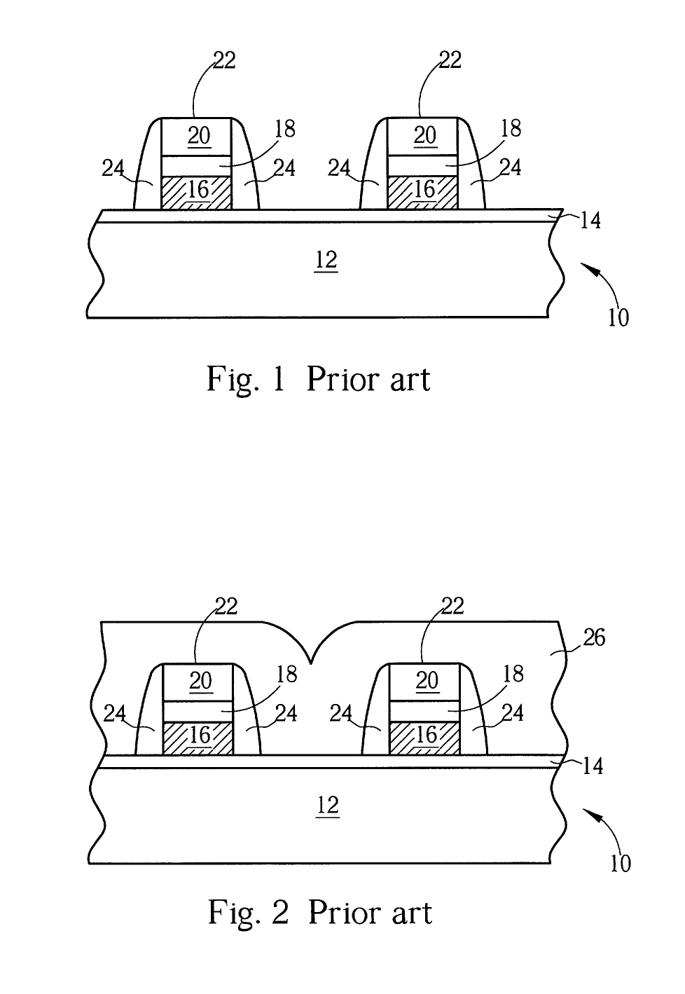

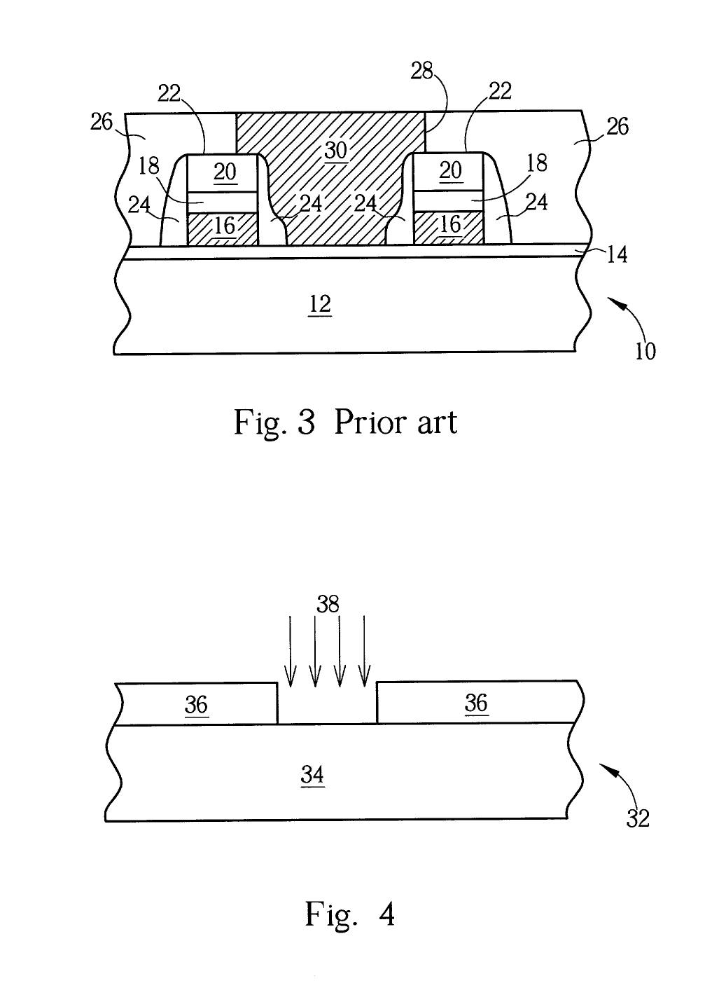

### DETAILED DESCRIPTION OF THE PREFERRED EMBODIMENT

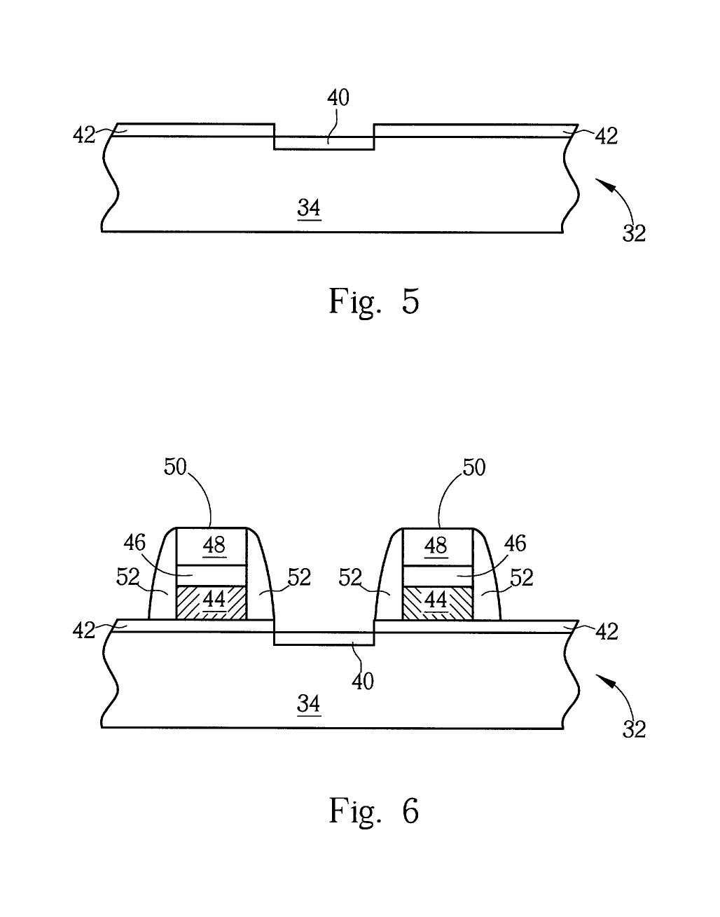

Please refer to FIG. 4 to FIG. 8. FIG. 4 to FIG. 8 are schematic diagrams of forming a contact pad 56 on a semiconductor wafer 32 according to the present invention. As shown in FIG. 4, a photoresist layer 36 is formed on a substrate 34 of the semiconductor wafer 32. A photolithographic process is performed using a photomask (not shown) to define a predetermined doped area (not shown) on the photoresist layer 36. An ion implantation process 38, using nitrogen (N₂) as the ion source, is performed on the predetermined doped area to anisotropically implant the substrate 34 uncovered by the photoresist layer 36 to form a doped area 40, as shown in FIG. 5.

After the photoresist layer 36 is removed, a thermal oxidation process is performed to grow a silicon oxide layer, functioning as a gate oxide layer 42, on the surface of the substrate 34. However, the nitrogen-implanted doped area 40 destroys the lattice structure within the substrate 34 to prevent the silicon oxide layer from growing on the surface of the doped area 40. As a result, the gate oxide layer 42 grows on the substrate 34, except in the doped area 40.

As shown in FIG. 6, at least one gate 50 is formed on the surface of the gate oxide layer 42. The method used to form the gate 50 is by a traditional gate fabrication process, involving the deposition of a doped polysilicon layer 44, a polycide layer 46 of titanium silicide (TiSiₓ), and a passivation layer 48 of silicon nitride (SiNₓ₎) on the gate oxide layer 42, respectively. A photolithographic process is also used to define the pattern of the gate 50 followed by etching of the doped polysilicon layer 44, the polycide layer 46 and the passivation layer 48. Finally, a spacer 52 of silicon nitride is formed on either side of the gate 50. The spacer 52 is used as a mask for the subsequent fabrication of a drain and source. The method of forming the drain and source of the MOS transistor is via a traditional ion implantation process, to implant the substrate 34 adjacent to the gate 50 as well as to form a doped area of minor carriers for connection to a bit line.

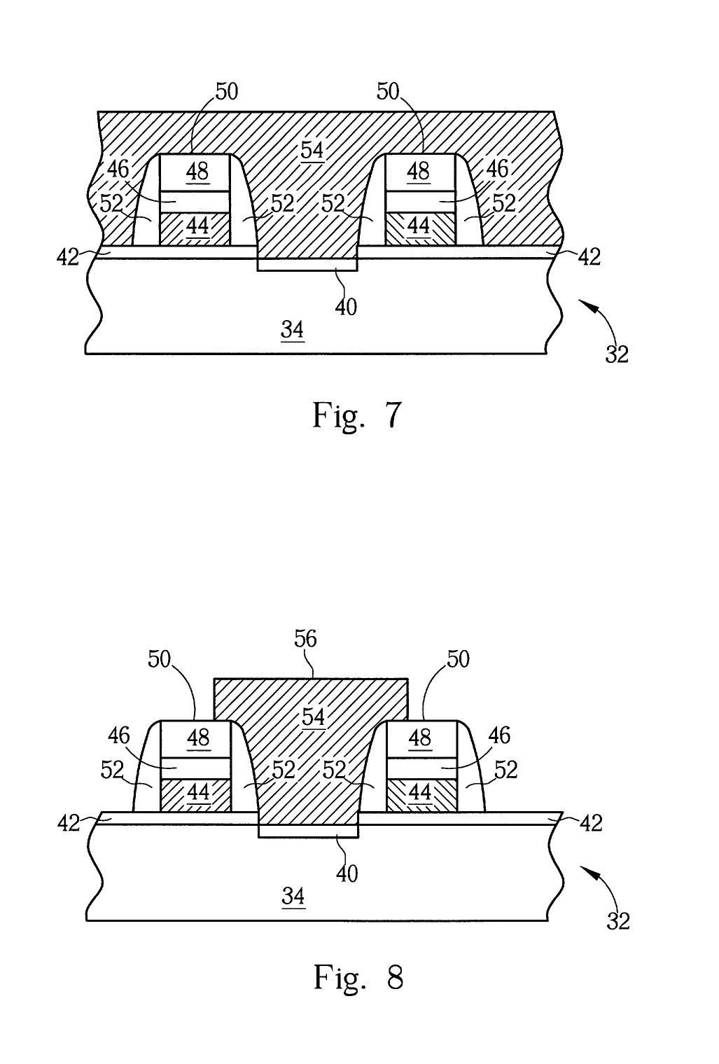

Subsequently, as shown in FIG. 7, a CVD process is performed to deposit a doped polysilicon layer 54 on the whole surface of the semiconductor wafer 32, with the doped polysilicon layer 54 completely filling in the gap between the two adjacent gates 50. A CMP process is also used to remove a portion of the doped polysilicon layer 54 to planarize the surface of the semiconductor wafer 32.

As shown in FIG. 8, a photoresist layer (not shown) is formed on the surface of the doped polysilicon layer 54, followed by the use of a photolithographic process to define the position of the contact pad 56 on the photoresist layer. When forming the pattern of the contact pad 56 on the photoresist layer, the prior mask used to define the doped area 40 is again used for pattern transfer according to the theory of the positive photoresist and negative photoresist. As a result, a pattern complementary to that of the doped area 40 is produced for the contact pad 56, to remove the process cost required for the formation of a new mask.

Finally, an etching process, using the gate oxide layer 42, the passivation layer 48 and the spacer 52 as a stop layer, is performed following pattern definition to remove a portion of the doped polysilicon layer 54 as well as to form the contact pad 56 between the two adjacent gates 50 and above the doped area 40. After the photoresist layer is removed, a CVD process is performed to deposit a dielectric layer (not shown) on the whole surface of the semiconductor wafer 32 to isolate the contact pad 56 from the other elements.

In the present invention, the doped polysilicon layer 54 is deposited, followed by the definition and patterning of the contact pad 56. Finally, a dielectric layer is formed to completely cover both the contact pad 56 and the gate 50. The formation of the node contact hole 28 within the dielectric layer 26, as mentioned in the prior art, is not required in the present invention. Hence, the problems of aspect ratio resulting from the filling of the doped polysilicon layer into the node contact hole 28 are prevented. As well, a uniform doped polysilicon layer is deposited to improve the performance of the contact pad 56.

In contrast to the prior method of forming a contact pad, the present invention uses a nitrogen ion implantation to control the growth region for the gate oxide layer, so that the gate oxide layer is only formed in the region where the gate will be formed. Hence, a conductive layer of the contact pad is directly deposited after the completion of the gate. As well, the etching process used to remove the dielectric layer within the node contact hole is no longer required and thus prevents the destruction of the spacer.

Furthermore, since better selectivity exists between the silicon nitride and the doped polysilicon, the thickness of the passivation layer of silicon nitride covering the top of the gate is decreased. As a result, the stress acting upon the passivation layer is also decreased to prevent the destruction of the gate. In conclusion, the present invention can effectively prevent the problems occurring in the prior method of forming the contact pad to thereby improve the production yield.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a contact pad on a semiconductor wafer, the semiconductor wafer comprising a substrate, the method comprising:
using a mask to perform a first photolithographic process to form a first photoresist layer on the surface of the substrate, the first photoresist layer covering the surface of the substrate except in a region where the contact pad will form;
using nitrogen to perform an ion implantation process on the portion of the substrate unprotected by the first photoresist layer;
removing the first photoresist layer;
growing a silicon oxide layer on the substrate, wherein the silicon oxide layer is prevented from growing in the region for forming the contact pad;
forming two adjacent metal-oxide semiconductor (MOS) transistors on the portions of the substrate adjacent to the region where the contact pad will form;
forming a conductive layer on the semiconductor wafer to cover the two adjacent MOS transistors as well as filling in the gap between the two MOS transistors;
using the mask to perform a second photolithographic process to form a patterned second photoresist layer on the surface of the conductive layer, the second photoresist layer defining the patterns of the contact pad; and
using the second photoresist layer as a mask to perform an etching process on the conductive layer, and stopping at the surface of each MOS transistor and the surface of the silicon oxide layer to form the contact pad.

2. The method of claim 1 wherein specific portions of the silicon oxide layer are used as the gate oxides of the MOS transistors.

3. The method of claim 2 wherein the silicon oxide layer, not used as the gate oxides of the MOS transistors, is used as a stop layer during the etching process.

4. The method of claim 1 wherein a thermal oxidation process is used to grow the silicon oxide layer on the substrate, while the ion implantation process is used to prevent the silicon oxide layer from growing on specific portions of the substrate.

5. The method of claim 1 wherein the substrate further comprises a source or a drain of the MOS transistor.

6. The method of claim 1 wherein the conductive layer is made of doped polysilicon.

7. A method of forming a contact pad on a semiconductor wafer, the semiconductor wafer comprising a substrate, the substrate comprising a first region and a second region, the first region being used to form a gate of a metal-oxide semiconductor (MOS) transistor, and the second region being used to form doped regions of the MOS transistor, the method comprising:
using nitrogen to perform an ion implantation process in the second region of the substrate;
performing a thermal oxidation process to grow a silicon oxide layer outside of the second region of the substrate, wherein the silicon oxide layer is prevented from growing in the second region after being performed by the ion implantation process;
forming two adjacent MOS transistors in the first region of the substrate; and
forming the contact pad in the gap between the two adjacent MOS transistors.

8. The method of claim 7 wherein specific portions of the silicon oxide layer are used as the gate oxides of the MOS transistors.

9. The method of claim 8 wherein the silicon oxide layer, not used as the gate oxides of the MOS transistors, is used a stop layer during the etching process.

10. The method of claim 7 wherein the ion implantation process is used to prevent silicon oxide from growing on the second region of the substrate.

11. The method of claim 7 wherein the substrate further comprises a source or a drain of the MOS transistor in the second region.

12. The method of claim 7 wherein the conductive layer is made of doped polysilicon.
